(19) United States
(12) Patent Application Publication
(10) Pub. No.: US 2026/0190532 A1
(43) Pub. Date: Jul. 2, 2026

(54) ELECTRONIC DEVICE

(71) Applicants: Innolux Corporation, Miaoli County (TW); InnoCare Optoelectronics Corporation, Tainan City (TW)

(72) Inventors: Hsin-Hung Lin, Tainan City (TW); Pei-Chih Liu, Miaoli County (TW); Sheng-Feng Huang, Miaoli County (TW)

(73) Assignees: Innolux Corporation, Miaoli County (TW); InnoCare Optoelectronics Corporation, Tainan City (TW)

(21) Appl. No.: 19/378,339

(22) Filed: Nov. 4, 2025

(30) Foreign Application Priority Data
Dec. 26, 2024 (TW) 113150894

(51) Int. Cl. H10F 39/95

(52) U.S. Cl. CPC H10F 39/95

(57) ABSTRACT

An electronic device includes a substrate, a pixel unit, a first chip on film and a second chip on film. The substrate has a first side and a second side opposite to each other. The pixel unit is disposed on the substrate. The first chip on film is disposed on the first side and is electrically connected to the pixel unit through a first wire. The second chip on film is disposed on the first side and is electrically connected to the pixel unit through a second wire. The first chip on film and the second chip on film respectively have different functions. The first chip on film at least partially overlaps the second chip on film.

### CROSS-REFERENCE TO RELATED APPLICATION

This application claims the priority benefits of Taiwan application serial no. 113150894, filed on December 26, 2024. The entirety of the above-mentioned patent application is hereby incorporated by reference herein and made a part of this specification.

### BACKGROUND

### Technical Field

The disclosure relates to an electronic device, and more particularly to an electronic device, which can reduce resistance capacitance load or increase frame rate.

### Description of Related Art

The electronic device or the spliced electronic device has been widely used in different fields such as communication, display, automotive, or aviation. With the rapid development of the electronic device, the electronic device is being developed toward being lighter and thinner, so the reliability or quality requirement for the electronic device is higher.

### SUMMARY

The disclosure provides an electronic device, which can reduce resistance capacitance (RC) loading or increase frame rate.

According to an embodiment of the disclosure, an electronic device includes a substrate, a pixel unit, a first chip on film, and a second chip on film. The substrate has a first side and a second side opposite to each other. The pixel unit is disposed on the substrate. The first chip on film is disposed on the first side and electrically connected to the pixel unit through a first wire. The second chip on film is disposed on the first side and electrically connected to the pixel unit through a second wire. The first chip on film and the second chip on film have different functions respectively. The first chip on film at least partially overlaps the second chip on film.

According to an embodiment of the disclosure, an electronic device includes a substrate, a pixel unit, and a first chip on film. The substrate has a first side and a second side opposite to each other. The pixel unit is disposed on the substrate. The first chip on film is disposed on the first side and has at least a first function and a second function. When the first chip on film executes the first function, the first chip on film is electrically connected to the pixel unit through a first wire. When the first chip on film executes the second function, the first chip on film is electrically connected to the pixel unit through a second wire.

To make the aforementioned more comprehensible, several embodiments accompanied with drawings are described in detail as follows.

### BRIEF DESCRIPTION OF THE DRAWINGS

FIG. 1A is a top schematic view of an electronic device according to a first embodiment of the disclosure.

FIG. 1B is a cross-sectional schematic view of the electronic device in FIG. 1A along section line I-I'.

FIG. 1C is a circuit schematic diagram of a pixel unit in the electronic device of FIG. 1A.

FIG. 2A is an enlarged schematic view of an area R1 of the electronic device in FIG. 1A.

FIG. 2B is a cross-sectional schematic view of the electronic device in FIG. 2A along section line II-II'.

FIG. 2C is a cross-sectional schematic view of the electronic device in FIG. 2A along section line III-III'.

FIG. 2D is a cross-sectional schematic view of the electronic device in FIG. 2A along section line IV-IV'.

FIG. 3A is a partial top schematic view of an electronic device according to a second embodiment of the disclosure.

FIG. 3B is a cross-sectional schematic view of the electronic device in FIG. 3A along section line V-V'.

FIG. 4 is a partial cross-sectional schematic view of an electronic device according to a third embodiment of the disclosure.

FIG. 5 is a top schematic view of an electronic device according to a fourth embodiment of the disclosure.

FIG. 6 is a top schematic view of an electronic device according to a fifth embodiment of the disclosure.

FIG. 7 is a top schematic view of an electronic device according to a sixth embodiment of the disclosure.

FIG. 8 is a top schematic view of an electronic device according to a seventh embodiment of the disclosure.

FIG. 9 is a top schematic view of an electronic device according to an eighth embodiment of the disclosure.

FIG. 10A is a top schematic view of an electronic device according to a ninth embodiment of the disclosure.

FIG. 10B is an enlarged schematic view of an area R2 of the electronic device in FIG. 10A.

FIG. 11 is a partial top schematic view of an electronic device according to a tenth embodiment of the disclosure.

### DESCRIPTION OF THE EMBODIMENTS

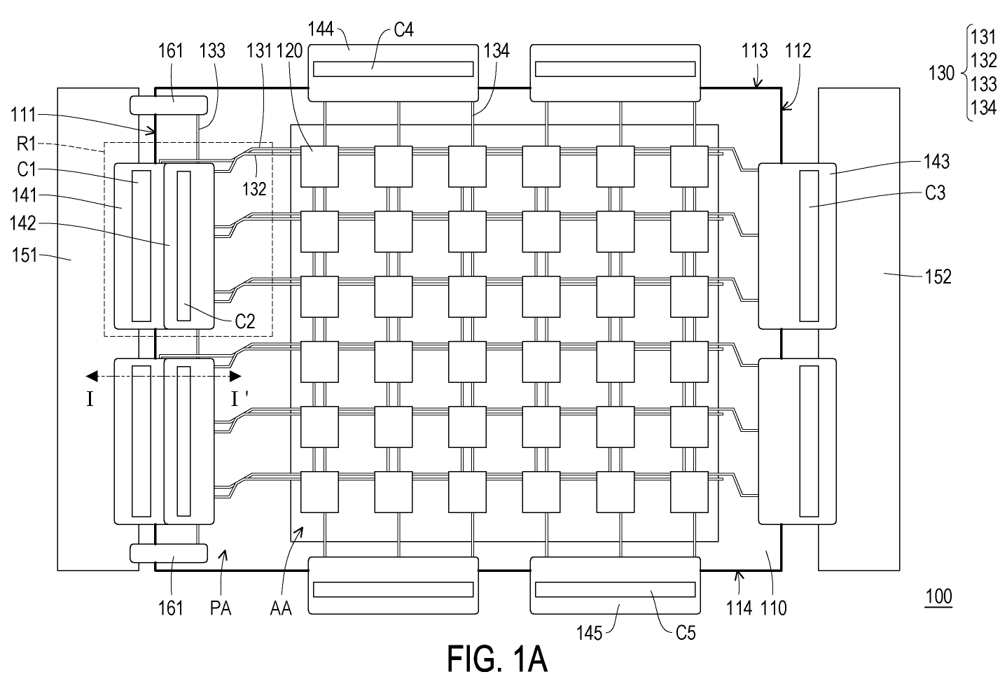

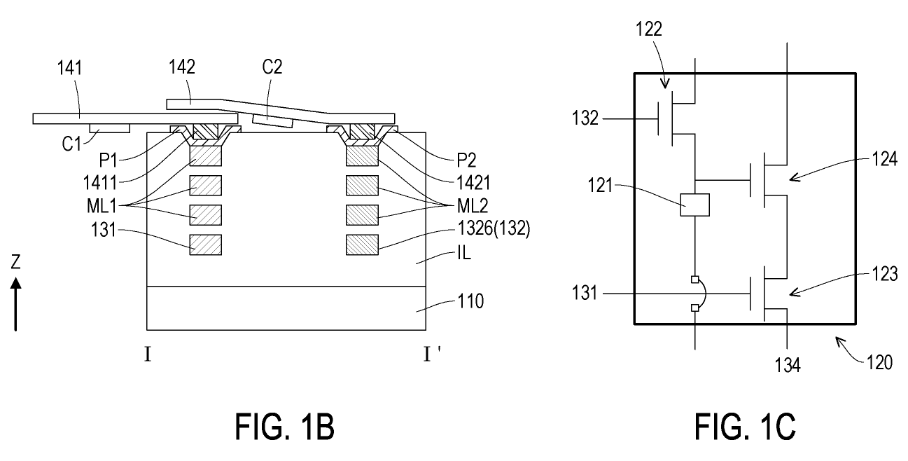

FIG. 1A is a top schematic view of an electronic device according to a first embodiment of the disclosure. FIG. 1B is a cross-sectional schematic view of the electronic device in FIG. 1A along section line I-I'. FIG. 1C is a circuit schematic diagram of a pixel unit in the electronic device of FIG. 1A. FIG. 2A is an enlarged schematic view of an area R1 of the electronic device in FIG. 1A. FIG. 2B is a cross-sectional schematic view of the electronic device in FIG. 2A along section line II-II'. FIG. 2C is a cross-sectional schematic view of the electronic device in FIG. 2A along section line III-III'. FIG. 2D is a cross-sectional schematic view of the electronic device in FIG. 2A along section line IV-IV'. For the sake of clarity and convenience of description, some elements of the electronic device are omitted from the illustrations in FIG. 1A and FIG. 2A.

Please refer to FIG. 1A and FIG. 1B. The electronic device 100 of the embodiment includes a substrate 110, a pixel unit 120, a circuit layer 130, a first chip on film (COF) 141, a second chip on film 142, a third chip on film 143, a fourth chip on film 144, a fifth chip on film 145, a first printed circuit board (PCB) 151, a second printed circuit board 152, and a first flexible printed circuit board (FPC) 161.

Specifically, the substrate 110 has a first side 111, a second side 112, a third side 113, and a fourth side 114. The first side 111 and the second side 112 are opposite to each other. The third side 113 connects the first side 111 and the second side 112, and the third side 113 is opposite to the fourth side 114. The substrate 110 further has an active region AA and a peripheral region PA adjacent to the active region AA. In the embodiment, the peripheral region PA may, for example, surround the active region AA, but is not limited thereto. In the embodiment, the substrate 110 may include rigid substrate materials, flexible substrate materials, or a combination thereof. For example, the material of the substrate 110 may include glass, quartz, sapphire, ceramic, polycarbonate (PC), polyimide (PI), polyethylene terephthalate (PET), other suitable substrate materials, or a combination thereof, but is not limited thereto.

Please refer to FIG. 1A and FIG. 1C. The pixel unit 120 is disposed on the substrate 110. The pixel unit 120 may, for example, be disposed on the active region AA in an array arrangement. The pixel unit 120 may include at least an electronic component 121, a switch component 122, a switch component 123, and a switch component 124. The electronic component 121 may be electrically connected to the switch component 122, and the switch component 123 may be electrically connected to the switch component 124. In the embodiment, the electronic component 121 may be a light detector, used to detect visible light and convert it into electrical signals, but is not limited thereto.

Please refer to FIG. 1A to FIG. 1C and FIG. 2A to FIG. 2D. The circuit layer 130 is disposed on the substrate 110. The circuit layer 130 includes an insulation layer IL, a first wire 131, a second wire 132, a third wire 133, a fourth wire 134, a pad P1, a pad P2, a metal layer ML1, and a metal layer ML2. The first wire 131, the second wire 132, the third wire 133, the fourth wire 134, the metal layer ML1, and the metal layer ML2 are disposed within the insulation layer IL. The first wire 131 may transmit signals to the switch component 123 to turn on the switch component 123. The second wire 132 may transmit signals to the switch component 122 to turn on the switch component 122. The fourth wire 134 may be electrically connected to the switch component 123. The pad P1 and the pad P2 are disposed on the insulation layer IL. The pad P1 may be electrically connected to the first wire 131 through the metal layer ML1, and the pad P2 may be electrically connected to the second wire 132 through the metal layer ML2.

In the embodiment, the insulation layer IL may be a multi-layer structure, and the material of the insulation layer IL may include organic materials, inorganic materials, or a combination thereof, but is not limited thereto. In the embodiment, the materials of the first wire 131, the second wire 132, the third wire 133, the fourth wire 134, the metal layer ML1, and the metal layer ML2 may include aluminum, copper, other suitable metals, or alloys or combinations of the aforementioned materials, but are not limited thereto. In the embodiment, the materials of the pad P1 and the pad P2 may include transparent conductive materials containing indium, tin, or zinc, but are not limited thereto. Furthermore, in the embodiment, the first wire 131 may be, for example, a scan line, the second wire 132 may be, for example, a reset line, and the fourth wire 134 may be, for example, a data line, but are not limited thereto.

Please refer to FIG. 1A, FIG. 2A, and FIG. 2B. In the embodiment, in the peripheral area PA of the substrate 110, the first wire 131 may partially overlap the second wire 132 in a normal direction Z of the substrate 110, to increase the layout space for other circuits, but is not limited thereto. Specifically, the first wire 131 may include a first part 1311, a second part 1312, and a third part 1313. The first part 1311 may extend from the peripheral area PA to the active region AA, and the first part 1311 is closer to the active region AA than the second part 1312 and the third part 1313; the second part 1312 is disposed between the first part 1311 and the third part 1313, and the second part 1312 may connect the first part 1311 and the third part 1313; the third part 1313 connects to the first chip on film 141, and the third part 1313 is closer to the first side 111 than the first part 1311 and the second part 1312. The second wire 132 may include a fourth part 1324, a fifth part 1325, and a sixth part 1326. The fourth part 1324 may extend from the peripheral area PA to the active region AA, and the fourth part 1324 is closer to the active region AA than the fifth part 1325 and the sixth part 1326; the fifth part 1325 is disposed between the fourth part 1324 and the sixth part 1326, and the fifth part 1325 may connect the fourth part 1324 and the sixth part 1326; the sixth part 1326 connects to the second chip on film 142, and the sixth part 1326 is closer to the first side 111 than the fourth part 1324 and the fifth part 1325. In the embodiment, the first wire 131 (including the first part 1311, the second part 1312, and the third part 1313) and one portion of the second wire 132 (i.e., the fourth part 1324 and the sixth part 1326) are disposed in the same layer, but the first wire 131 (including the first part 1311, the second part 1312, and the third part 1313) and the other portion of the second wire 132 (i.e., the fifth part 1325) are disposed in different layers. Among them, the first part 1311 and the fourth part 1324 are disposed apart, the third part 1313 and the sixth part 1326 are disposed apart, the fifth part 1325 is disposed on the second part 1312, and the fifth part 1325 may overlap the second part 1312 in the normal direction Z of the substrate 110, but is not limited thereto.

Please refer to FIG. 1A, FIG. 1B, and FIG. 2A. The first chip on film 141 is disposed on the first side 111 of the substrate 110. The first chip on film 141 includes a first chip C1 and a first pad 1411. The first chip C1 may be used to execute a first function and is electrically connected to the first pad 1411. The first chip on film 141 may be bonded to the pad P1 of the circuit layer 130 through the first pad 1411. The first chip on film 141 may be electrically connected to the pixel unit 120 through the first pad 1411, the pad P1, the metal layer ML1, and the first wire 131, thereby enabling the first chip on film 141 to execute the first function to turn on the switch component 123 in the pixel unit 120.

Please refer to FIGS. 1A, FIG. 1B, FIG. 2A. The second chip on film 142 is disposed on the first side 111 of the substrate 110, thereby enabling the second chip on film 142 and the first chip on film 141 to be disposed on the same side of the substrate 110 (e.g., the first side 111). The second chip on film 142 may at least partially overlap the first chip on film 141 in the normal direction Z of the substrate 110. The second chip on film 142 includes a second chip C2 and a second pad 1421. The second chip C2 may be used to execute a second function and is electrically connected to the second pad 1421. The second chip on film 142 may be bonded to the pad P2 of the circuit layer 130 through the second pad 1421. The second chip on film 142 may be electrically connected to the pixel unit 120 through the second pad 1421, the pad P2, the metal layer ML2, and the second wire 132, thereby enabling the second chip on film 142 to execute the second function to turn on the switch component 122 in the pixel unit 120. In the embodiment, the first chip on film 141 and the second chip on film 142 have different functions respectively. Moreover, in the embodiment, the first chip on film 141 is not directly electrically connected to the second chip on film 142, but this is not limited thereto.

Please refer to FIG. 1A. The third chip on film 143 is disposed on the second side 112. The third chip on film 143 includes a chip C3, which may be used to execute the first function. The third chip on film 143 may be electrically connected to the pixel unit 120 through the first wire 131, thereby enabling the third chip on film 143 to execute the first function to turn on the switch component 123 in the pixel unit 120. In the embodiment, the first chip on film 141 and the third chip on film 143 have the same function.

Please refer to FIG. 1A. The fourth chip on film 144 is disposed on the third side 113. The fourth chip on film 144 includes a chip C4, which may be used to execute a third function. The fourth chip on film 144 may be electrically connected to the pixel unit 120 through the fourth wire 134, thereby enabling the fourth chip on film 144 to execute the third function. In the embodiment, the first chip on film 141, the second chip on film 142, and the fourth chip on film 144 have different functions respectively.

Please refer to FIG. 1A. The fifth chip on film 145 is disposed on the fourth side 114. The fifth chip on film 145 includes a chip C5, which may be used to execute the third function. The fifth chip on film 145 may be electrically connected to the pixel unit 120 through the fourth wire 134, thereby enabling the fifth chip on film 145 to execute the third function. In the embodiment, the fourth chip on film 144 and the fifth chip on film 145 have the same function.

Please refer to FIG. 1A. The first circuit board 151 is disposed adjacent to the first side 111 of the substrate 110. The first circuit board 151 may be electrically connected to the first chip on film 141 to provide external signals to the first chip on film 141.

Please refer to FIG. 1A. The second circuit board 152 is disposed adjacent to the second side 112 of the substrate 110. The second circuit board 152 may be electrically connected to the third chip on film 143 to provide external signals to the third chip on film 143.

Please refer to FIG. 1A. The first flexible circuit board 161 is disposed on the first side 111 of the substrate 110. The first flexible circuit board 161 may be electrically connected to the second chip on film 142 through the third wire 133. In the embodiment, the first circuit board 151 may be electrically connected to the first flexible circuit board 161, and the first circuit board 151 may be electrically connected to the second chip on film 142 through the first flexible circuit board 161 to provide external signals to the second chip on film 142, but is not limited thereto.

In the embodiment, by disposing the first chip on film 141 and the third chip on film 143, which have the same function, on the first side 111 and the second side 112 of the substrate 110 respectively, the pixel unit 120 in the active region AA may receive driving signals from two opposite sides of the substrate 110, thereby reducing the overall resistance capacitance load or increasing the frame rate.

In the embodiment, by means of the design and arrangement of the first wire 131, the second wire 132, the pad P1, the pad P2, the metal layer ML1, and the metal layer ML2 in the circuit layer 130, the first chip on film 141 and the second chip on film 142 with different functions may be disposed on the same side of the substrate 110 (for example, the first side 111), and the first chip on film 141 and the second chip on film 142 may overlap in the normal direction Z of the substrate 110.

The following will list other embodiments for illustration. It must be explained here that the following embodiments adopt the element labels and part of the content from the aforementioned embodiments, where the same labels are used to represent the same or similar elements, and the explanation of the same technical content is omitted. For the explanation of the omitted parts, please refer to the aforementioned embodiments, and the following embodiments will not repeat the redundant descriptions.

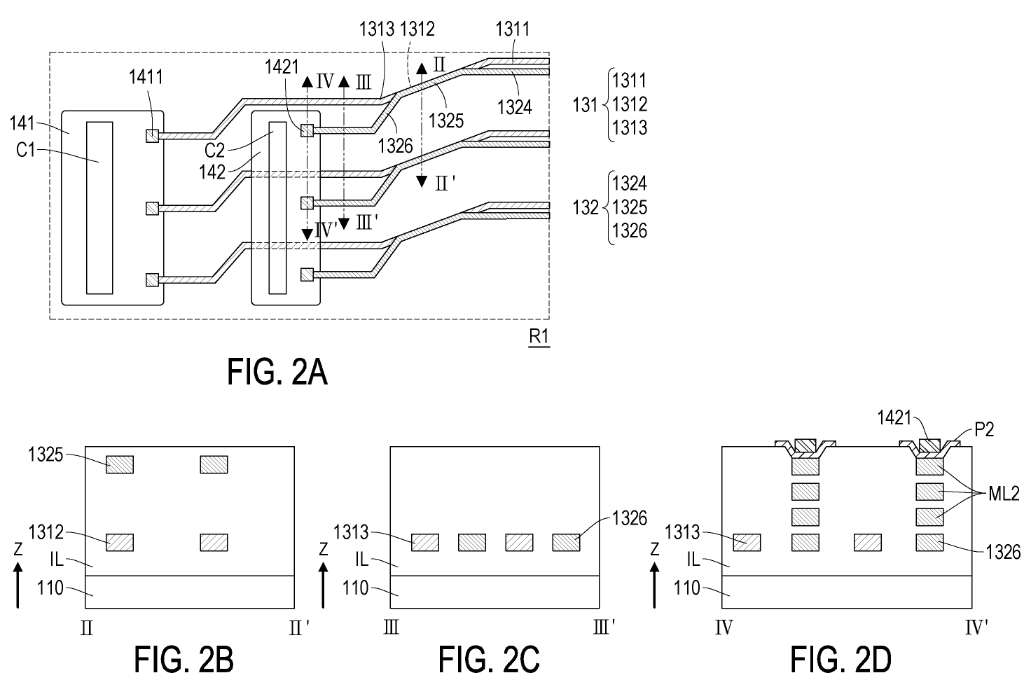

FIG. 3A is a partial top schematic view of an electronic device according to a second embodiment of the disclosure. FIG. 3B is a cross-sectional schematic view of the electronic device in FIG. 3A along section line V-V'. Please refer to FIG. 3A to FIG. 3B and FIG. 2A to FIG. 2B simultaneously. The electronic device 100a of the embodiment resembles the electronic device 100 in FIG. 2A to FIG. 2B, but the difference between both is: in the electronic device 100a of the embodiment, the second part 1312 of the first wire 131 does not overlap the fifth part 1325a of the second wire 132 in the normal direction Z of the substrate 110, thereby reducing the parasitic capacitance between the second part 1312 and the fifth part 1325a.

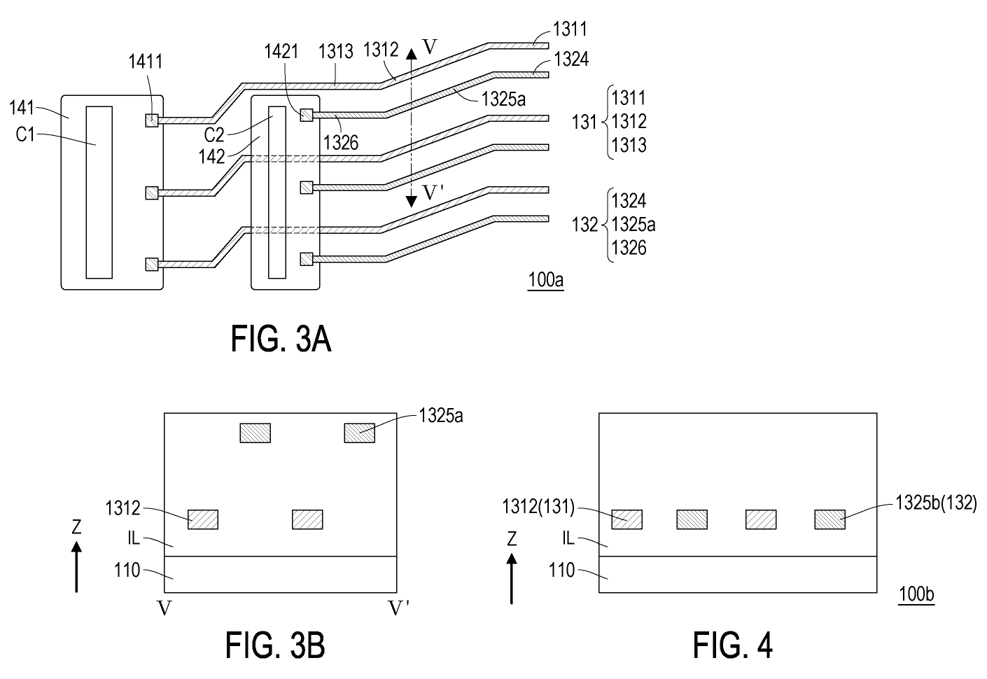

FIG. 4 is a partial cross-sectional schematic view of an electronic device according to a third embodiment of the disclosure. Please refer to FIG. 4 and FIG. 3B simultaneously. The electronic device 100b of the embodiment resembles the electronic device 100a in FIG. 3B, but the difference between both is: in the electronic device 100b of the embodiment, the second part 1312 of the first wire 131 and the fifth part 1325b of the second wire 132 are disposed on the same layer.

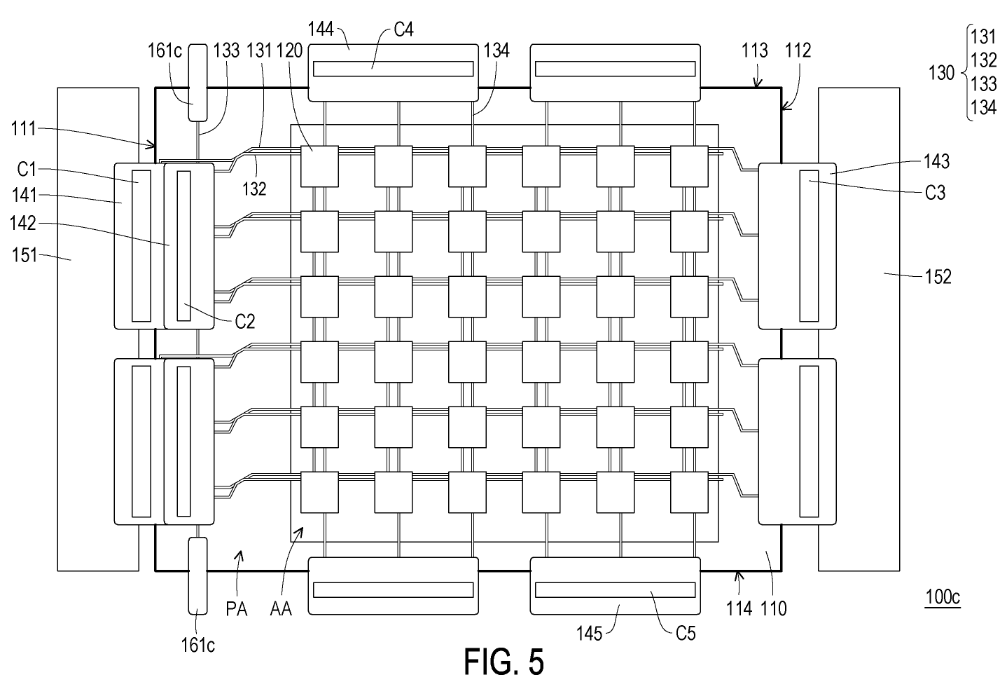

FIG. 5 is a top schematic view of an electronic device according to a fourth embodiment of the disclosure. Please refer to FIG. 5 and FIG. 1A simultaneously. The electronic device 100c of the embodiment resembles the electronic device 100 in FIG. 1A, but the difference between both is: in the electronic device 100c of the embodiment, the first flexible printed circuit board 161c is disposed on the third side 113 and the fourth side 114 of the substrate 110, the first flexible printed circuit board 161c is not electrically connected to the first printed circuit board 151, and the first flexible printed circuit board 161c may be electrically connected to a motherboard (not shown) or other printed circuit boards (not shown) disposed adjacent to the third side 113 or the fourth side 114 of the substrate 110. Thereby, external signals from the motherboard or other printed circuit boards may be provided to the second chip on film 142 through the first flexible printed circuit board 161c.

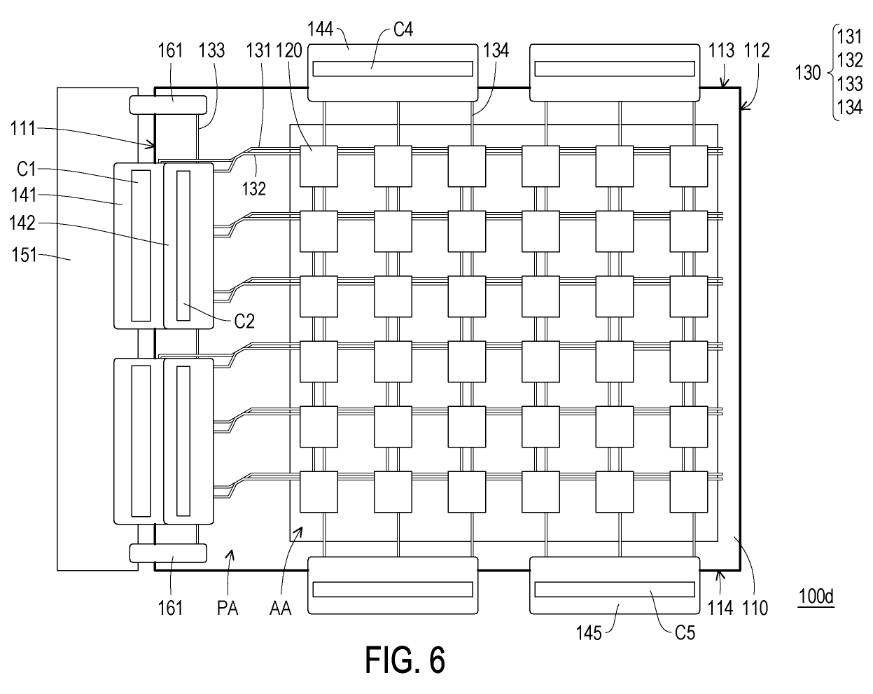

FIG. 6 is a top schematic view of an electronic device according to a fifth embodiment of the disclosure. Please refer to FIG. 6 and FIG. 1A simultaneously. The electronic device 100d of the embodiment resembles the electronic device 100 in FIG. 1A, but the difference between both is: in the electronic device 100d of the embodiment, the setting of the third chip on film is omitted to reduce the width of the peripheral area PA adjacent to the second side 112 of the substrate 110, thereby achieving a narrow border effect.

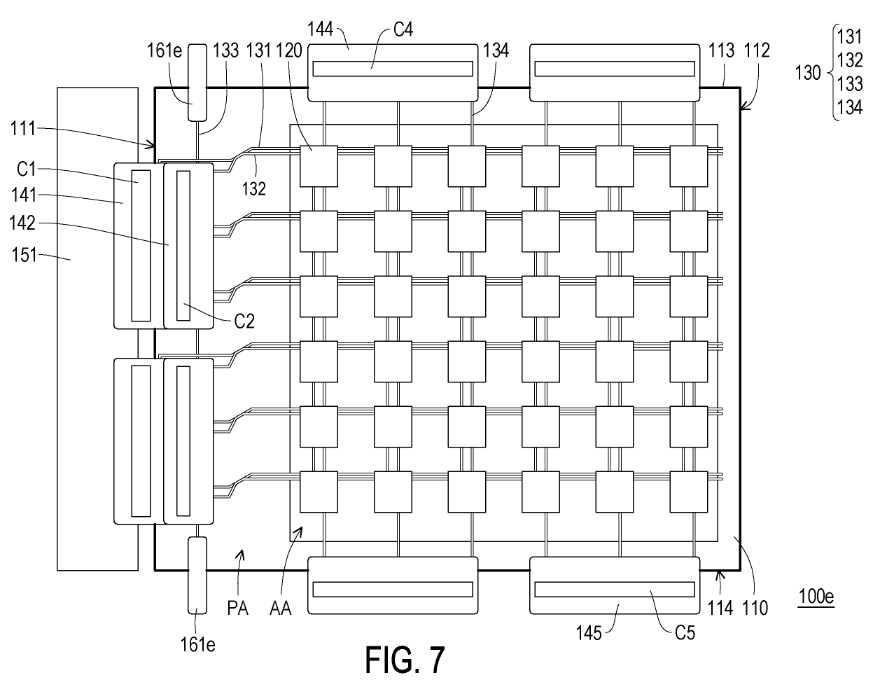

FIG. 7 is a top schematic view of an electronic device according to a sixth embodiment of the disclosure. Please refer to FIG. 7 and FIG. 6 simultaneously. The electronic device 100e of the embodiment resembles the electronic device 100d in FIG. 6, but the difference between both is: in the electronic device 100e of the embodiment, the first flexible printed circuit board 161e is disposed on the third side 113 and the fourth side 114 of the substrate 110, the first flexible printed circuit board 161e is not electrically connected to the first printed circuit board 151, and the first flexible printed circuit board 161e may be electrically connected to a motherboard (not shown) or other printed circuit boards (not shown) disposed adjacent to the third side 113 or the fourth side 114 of the substrate 110. Thereby, external signals from the motherboard or other printed circuit boards may be provided to the second chip on film 142 through the first flexible printed circuit board 161e.

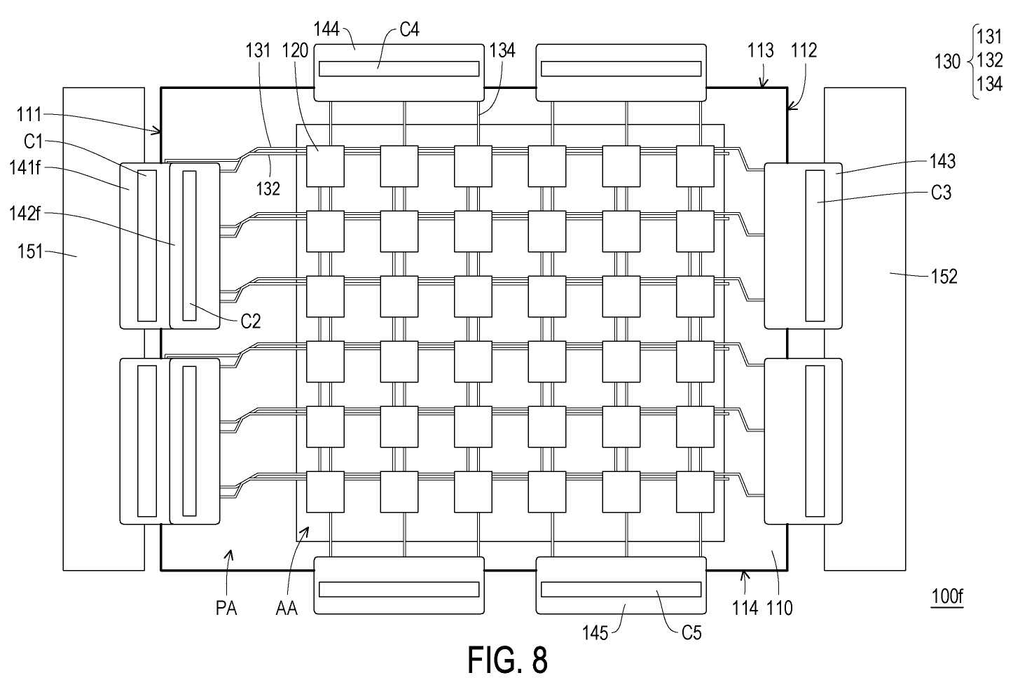

FIG. 8 is a top schematic view of an electronic device according to a seventh embodiment of the disclosure. Please refer to FIG. 8 and FIG. 1A simultaneously. The electronic device 100f of the embodiment resembles the electronic device 100 in FIG. 1A, but the difference between both is: in the electronic device 100f of the embodiment, the setting of the first flexible printed circuit board and the third wire is omitted, and the first chip on film 141f may be electrically connected to the second chip on film 142f. Thereby, the first printed circuit board 151 may be electrically connected to the second chip on film 142f through the first chip on film 141f, and external signals from the first printed circuit board 151 may be provided to the second chip on film 142f through the first chip on film 141f.

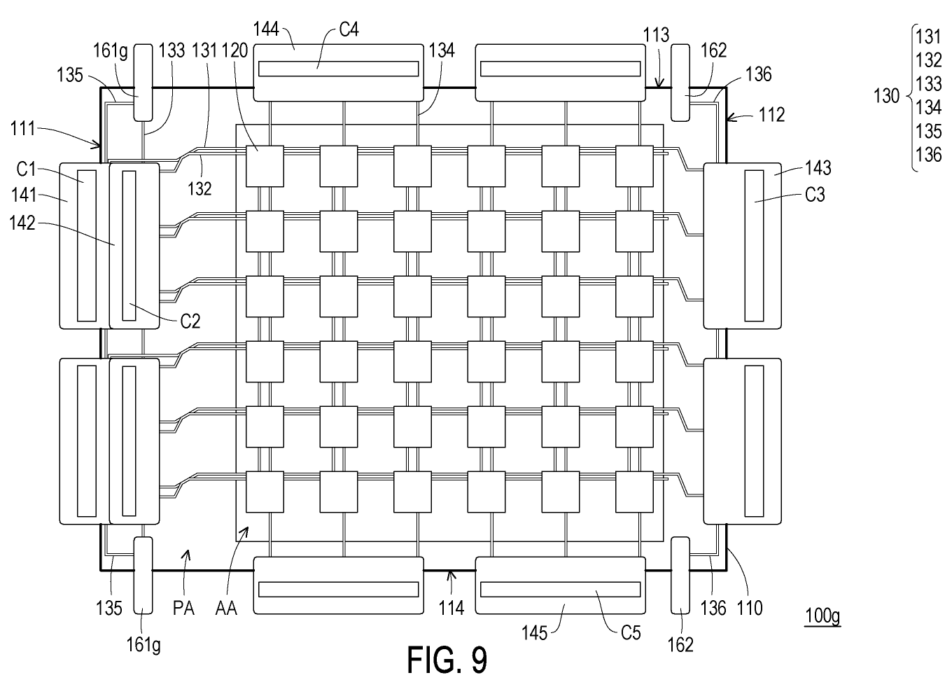

FIG. 9 is a top schematic view of an electronic device according to an eighth embodiment of the disclosure. Please refer to FIG. 9 and FIG. 1A simultaneously. The electronic device 100g of the embodiment resembles the electronic device 100 in FIG. 1A, but the difference between both is: in the electronic device 100g of the embodiment, the setting of the first printed circuit board and the second printed circuit board is omitted, and the electronic device 100g may further include a second flexible printed circuit board 162, the circuit layer 130 further includes a fifth wire 135 and a sixth wire 136.

Specifically, please refer to FIG. 9, the first flexible printed circuit board 161g is disposed on the third side 113 and the fourth side 114 of the substrate 110, the first flexible printed circuit board 161g may be electrically connected to the first chip on film 141 through the fifth wire 135, and the first flexible printed circuit board 161g may also be electrically connected to the second chip on film 142 through the third wire 133.

The second flexible printed circuit board 162 is disposed on the third side 113 and the fourth side 114 of the substrate 110, and the second flexible printed circuit board 162 may be electrically connected to the third chip on film 143 through the sixth wire 136.

The first flexible printed circuit board 161g and the second flexible printed circuit board 162 may be electrically connected to a motherboard (not shown) or other printed circuit boards (not shown) disposed adjacent to the third side 113 or the fourth side 114 of the substrate 110. Thereby, external signals from the motherboard or other printed circuit boards may be provided to the first chip on film 141 and the second chip on film 142 through the first flexible printed circuit board 161g, and provided to the third chip on film 143 through the second flexible printed circuit board 162.

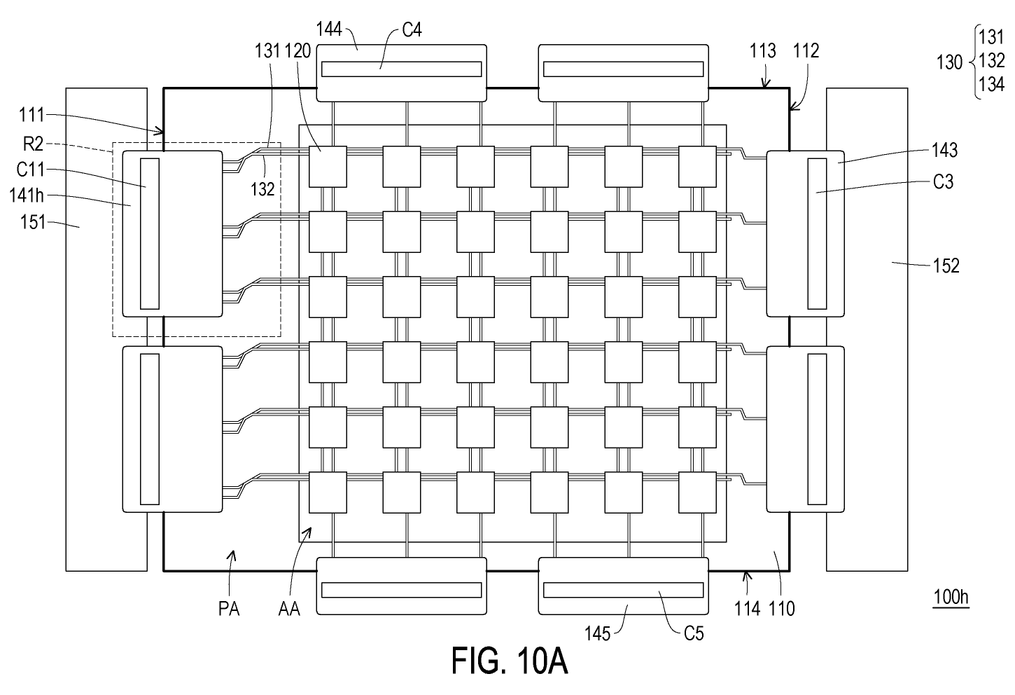

FIG. 10A is a top schematic view of an electronic device according to a ninth embodiment of the disclosure. FIG. 10B is an enlarged schematic view of an area R2 of the electronic device in FIG. 10A. Please refer to FIG. 10A to FIG. 10B, FIG. 1A and FIG. 2A simultaneously. The electronic device 100h of the embodiment resembles the electronic device 100 in FIG. 1A and FIG. 2A, but the difference between both is: in the electronic device 100h of the embodiment, the setting of the second chip on film, the first flexible printed circuit board and the third wire is omitted, and the first chip on film 141h has at least a first function and a second function.

Specifically, please refer to FIG. 10A and FIG. 10B, the first chip on film 141h includes a first chip C11, a first pad 1411 and a second pad 1412. The first chip C11 may be a multi-functional chip, and the first chip C11 may be used to execute at least the first function and the second function. The first chip C11 may be electrically connected to the first pad 1411 and the second pad 1412 respectively.

The first pad 1411 may be electrically connected to the first wire 131. Thereby, when the first chip C11 of the first chip on film 141h executes the first function, the first chip C11 may be electrically connected to the pixel unit 120 through the first pad 1411 and the first wire 131.

The second pad 1412 may be electrically connected to the second wire 132. Thereby, when the first chip C11 of the first chip on film 141h executes the second function, the first chip C11 may be electrically connected to the pixel unit 120 through the second pad 1412 and the second wire 132.

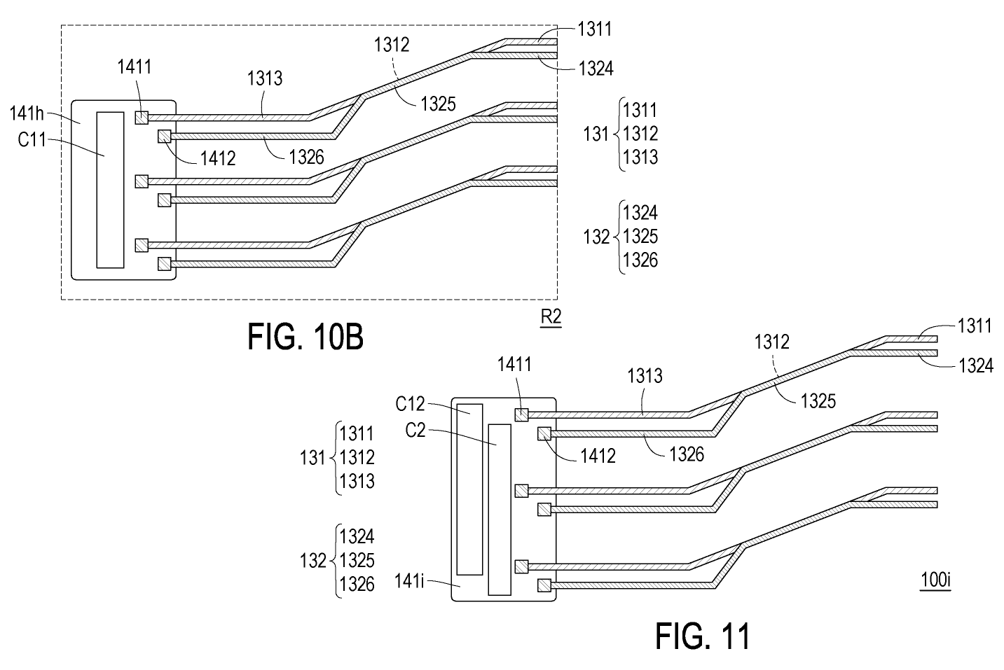

FIG. 11 is a partial top schematic view of an electronic device according to a tenth embodiment of the disclosure. Please refer to FIG. 11 and FIG. 10B simultaneously. The electronic device 100i of the embodiment resembles the electronic device 100h in FIG. 10B, but the difference between both is: in the electronic device 100i of the embodiment, the first chip C12 does not have the second function, and the first chip on film 141i further includes a second chip C2.

Specifically, please refer to FIG. 11, the first chip C12 may be used to execute the first function, and the first chip C12 may be electrically connected to the first pad 1411. Thereby, when the first chip C12 of the first chip on film 141i executes the first function, the first chip C12 may be electrically connected to the pixel unit (not shown) through the first pad 1411 and the first wire 131.

The second chip C2 may be used to execute the second function, and the second chip C2 may be electrically connected to the second pad 1412. Thereby, when the second chip C2 of the first chip on film 141i executes the second function, the second chip C2 may be electrically connected to the pixel unit (not shown) through the second pad 1412 and the second wire 132.

In summary, in an electronic device of an implementation of the disclosure, by setting the first chip on film and the third chip on film with the same function on the first side and the second side of the substrate respectively, the pixel unit in the active region may receive driving signals from both sides of the substrate, thereby reducing the overall resistance capacitance load or increasing the frame rate. Moreover, through the design and arrangement of wires, pads, and metal layers in the circuit layer, the first chip on film and the second chip on film with different functions may be disposed on the same side of the substrate (e.g., the first side) and may overlap in the normal direction of the substrate.

Although the disclosure has been revealed by the above embodiments, it is not intended to limit the scope of the disclosure. Any person skilled in the art may make minor modifications and refinements without departing from the spirit and scope of the disclosure. Therefore, the protection scope of the disclosure should be defined by the appended patent claims.

What is claimed is:

1. An electronic device, comprising:
a substrate, having a first side and a second side opposite to each other;
a pixel unit, disposed on the substrate;
a first chip on film, disposed on the first side, and electrically connected to the pixel unit through a first wire; and
a second chip on film, disposed on the first side, and electrically connected to the pixel unit through a second wire;
wherein the first chip on film and the second chip on film respectively have different functions, and the first chip on film at least partially overlaps the second chip on film.

2. The electronic device according to claim 1, wherein the first wire partially overlaps the second wire.

3. The electronic device according to claim 1, wherein the first wire does not overlap the second wire.

4. The electronic device according to claim 1, further comprising:
a first printed circuit board, adjacent to the first side of the substrate, and electrically connected to the first chip on film.

5. The electronic device according to claim 4, further comprising:
a first flexible printed circuit board, disposed on the first side of the substrate, and electrically connected to the second chip on film through a third wire.

6. The electronic device according to claim 5, wherein the first printed circuit board is electrically connected to the second chip on film through the first flexible printed circuit board.

7. The electronic device according to claim 5, wherein the first printed circuit board is electrically connected to the second chip on film through the first chip on film.

8. The electronic device according to claim 1, further comprising:
a third chip on film, disposed on the second side, and electrically connected to the pixel unit through the first wire,
wherein the first chip on film and the third chip on film have the same function.

9. The electronic device according to claim 8, further comprising:
a second printed circuit board, adjacent to the second side of the substrate, and electrically connected to the third chip on film.

10. The electronic device according to claim 1, wherein the substrate further has a third side connecting the first side and the second side, and the electronic device further comprises:
a fourth chip on film, disposed on the third side, and electrically connected to the pixel unit through a fourth wire,
wherein the first chip on film, the second chip on film, and the fourth chip on film respectively have different functions.

11. The electronic device according to claim 10, wherein the substrate further has a fourth side opposite to the third side, and the electronic device further comprises:
a fifth chip on film, disposed on the fourth side, and electrically connected to the pixel unit through the fourth wire,
wherein the fourth chip on film and the fifth chip on film have the same function.

12. The electronic device according to claim 1, further comprising:
a first flexible printed circuit board, disposed on the first side of the substrate, electrically connected to the second chip on film through a third wire, and electrically connected to the first chip on film through a fifth wire.

13. The electronic device according to claim 11, further comprising:
a third chip on film, disposed on the second side, and electrically connected to the pixel unit through the first wire; and
a second flexible printed circuit board, disposed on the second side, and electrically connected to the third chip on film through a sixth wire.

14. An electronic device, comprising:
a substrate, having a first side and a second side opposite to each other;
a pixel unit, disposed on the substrate; and
a first chip on film, disposed on the first side, and having at least a first function and a second function;
wherein when the first chip on film executes the first function, the first chip on film is electrically connected to the pixel unit through a first wire,
wherein when the first chip on film executes the second function, the first chip on film is electrically connected to the pixel unit through a second wire.

15. The electronic device according to claim 14, wherein the first chip on film comprises:
a first chip, electrically connected to the first wire; and
a second chip, electrically connected to the second wire.

16. The electronic device according to claim 14, wherein the first wire partially overlaps the second wire.

17. The electronic device according to claim 14, further comprising:
a first printed circuit board, adjacent to the first side of the substrate, and electrically connected to the first chip on film.

18. The electronic device according to claim 14, further comprising:
a third chip on film, disposed on the second side, and electrically connected to the pixel unit through the first wire,
wherein the third chip on film has the first function.

19. The electronic device according to claim 14, wherein the substrate further has a third side connecting the first side and the second side, and the electronic device further comprises:
a fourth chip on film, disposed on the third side, and electrically connected to the pixel unit through a fourth wire,
wherein the first chip on film and the fourth chip on film respectively have different functions.

20. The electronic device according to claim 19, wherein the substrate further has a fourth side opposite to the third side, and the electronic device further comprises:
a fifth chip on film, disposed on the fourth side, and electrically connected to the pixel unit through the fourth wire,
wherein the fourth chip on film and the fifth chip on film have the same function.
